(19) United States
(12) Patent Application Publication
(10) Pub. No.: US 2006/0231375 A1
(43) Pub. Date: Oct. 19, 2006

(54) Method for operating an electrical appliance

(75) Inventor: Andreas Kleinhans, Bretten (DE)

Correspondence Address: AKERMAN SENTERFITT, P.O. BOX 3188, WEST PALM BEACH, FL, 33402-3188, US

(73) Assignee: E.G.O. Elektro-Geraetebau GmbH, Oberderdingen (DE)

(21) Appl. No.: 11/336,449

(22) Filed: Jan. 20, 2006

(30) Foreign Application Priority Data
Jan. 20, 2005 (DE) 102005004066.7

(51) Int. Cl. H03K 17/975

(52) U.S. Cl. 200/600

(57) ABSTRACT

In the case of an electrical appliance, such as a hob with contact or touch switches under a glass ceramic hotplate, it is possible to provide on at least some contact switches an operating function initiated following double contacting or touching in a time of max. two seconds. If only a single contacting or three or more contacting operations take place within this time period, then no operating function is initiated and instead an error signal is outputted.

The following disclosure is based on German Patent Application No. 102005004066.7 filed on Jan. 20, 2005, which is herewith incorporated into this application by explicit reference.

### FIELD OF APPLICATION AND PRIOR ART

The invention relates to an operating method for an electrical appliance by means of a touch or contact switch or touch or contact sensor on an operating surface and an operating device.

It is known from U.S. Pat. No. 5,917,165 to provide contact switches below the glass ceramic plate on a glass ceramic hob. If a finger is placed on such a contact switch or on the glass ceramic plate above said contact switch, it is possible to initiate a function. As a result of the nature of contact switches for whose operation, in certain circumstances, there is no need to cover a mechanical operating path, a relatively weak touching with the finger or the application of a finger is sufficient. Faults or incorrect operations are eliminated or suppressed by such a control in that only operations or sensor signals in a predetermined area or in a predetermined manner are defined as appropriate, desired actuations. It is e.g. possible to classify an excessively long actuation of the contact switch by an object placed over it as an error or inappropriate actuation, e.g. if it lasts longer than three or ten seconds. It can then be assumed that it is not a planned actuation with the finger of an operator, but instead e.g. an accidentally set down object, which also trips the contact switch. However, it is disadvantageous that a relatively large amount of time is needed to detect such an inappropriate actuation. As a result there is a risk of operating errors or even injuries or damage as a result of an undesirably operating electrical appliance.

### PROBLEM AND SOLUTION

The problem of the invention is to provide an operating method and operating device making it possible to avoid the prior art problems and which in particular in a novel and advantageous manner make more safe and reliable the actuation of an electrical appliance with contact switches.

This problem is solved by an operating method having the features of claim 1 and a device for performing the operating method having the features of claim 11. Advantageous and preferred developments of the invention can be gathered from the further claims and are explained in greater detail hereinafter. By express reference the wording of the claims is made into part of the content of the description.

According to the invention through twice or several times in succession touching the operating surface or by means of the contact switch, which hereinafter is equated with the contact sensor, within a specific time or with a specific frequency a defined operating function is initiated. This means that e.g. through twice touching or contacting the operating surface or contact switch a corresponding, associated function is initiated if no more than a specific time elapses between the two actuations. It is thus possible to provide for the maximum intermediate time to be one second. It is e.g. also possible that within two seconds for a further operating function a triple actuation must take place or the contact switch must be contacted a third time.

If the predefined number of contacts does not take place within a specific time, either a fault or error signal is outputted or there is no reaction and in particular no operating function. It is particularly advantageous that the multiple contact or actuation can take place at the same point or on the same contact switch. It is admittedly also fundamentally possible to successively actuate two different contact switches within the prescribed time. However, this makes operation more difficult for an operator, because a change of actuation location within a short time is difficult or can give rise to operating errors.

Advantageously the appropriate and correct operation or initiation is fixed in such a way that it can easily be performed with the necessary repetition and/or speed. It is suitable for this purpose to effect a gentle touching operation, which can even be heard in certain circumstances.

As the time interval in which operation or the operating process has to take place, it is advantageous to have periods of a few seconds. It is e.g. possible to provide for two successive actuations to have no more than two seconds between them and advantageously roughly one second or even less.

It is advantageously provided on such a contact switch or with such an operating function that when operation or actuation only takes place once, no operating function is initiated. Only when the prescribed, multiple actuation has taken place within a specific time is an associated operating function initiated. As has already been stated, the inappropriate operation or operating attempt can be indicated to an operator.

It is also possible to design a contact switch in such a way that at a specific time, e.g. when the electrical appliance is switched off, said electrical appliance is switched on after contacting twice within a short time. The function can then be changed and it can operate as a contact switch which initiates an operating function after only contacting once. Thus, as a result of the operating method according to the invention there can be a type of safety function and a multiple use of a contact switch.

It is also possible to design a contact switch in such a way that on actuating twice within a short time, a first specific function is implemented and on actuating three times a different, second function is actuated. This permits a further multiple use of contact switches and the number thereof can be reduced. This allows the construction of more favourable and in particular smaller operating units.

It is e.g. possible for an operator to individually set within a control mechanism of the electrical appliance how long the time intervals are to be within which multiple actuation has to take place. This permits an individual adaptation enabling each individual operator to find the most promising and practically advantageous setting.

It is also possible for each individual contacting of a contact switch to be optically or acoustically acknowledged, e.g. with a short signal tone. After the operating function has correctly been initiated this is also advantageously indicated.

The invention makes it possible to associate an operating function with a multiple operation of a contact switch within a short, predetermined time. It is possible to look upon as an operation a single operating action not followed by a second operating action within a predetermined time and associate or initiate an operating function. It is also possible to provide a specific, associated operating function with a further extending three or many times operation, e.g. the triple touching of a contact switch.

It is alternatively possible on a contact switch in general or at specific points within an operating menu for an operating function to be initiated exclusively by a double touching or actuation. Thus, as a function of needs, emphasis can be placed either on an increased operating security, or implementing a maximum number of operating functions by a type of multiple functionality with a small number of contact switches.

An electrical appliance in which the inventive method is implemented by the inventive operating device, can advantageously be a domestic electrical appliance, particularly one having a large number of functions such as e.g. a hob or a cooker. The contact switches or sensors are located on a contact surface. Such a contact surface can have several, but in certain circumstances only a single contact switch or sensor. In the case of a hob, it can e.g. be a part of the glass ceramic plate serving as the hob plate, particularly in a front area. The contact switches can also be placed under a frame surrounding the hob plate.

In connection with the contact switches it is also pointed out that they are advantageously chosen in such a way that for their operation or initiation no or a relatively small initiating path is required, as well as a relatively small actuating or initiating force. Particular suitability exists in the case of contact switches not having an initiating path or without a mechanical function, particularly capacitive or optical contact switches.

These and further features can be gathered from the claims, description and drawings and the individual features, both singly or in the form of subcombinations, can be implemented in an embodiment of the invention and in other fields and can represent advantageous, independently protectable constructions for which protection is claimed here. The subdivision of the application into individual sections and the subheadings in no way restrict the general validity of the statements made thereunder.

### BRIEF DESCRIPTION OF THE DRAWING

FIG. 1 diagrammatically shows in section an operating device according to the invention for describing the operating method in question.

### DETAILED DESCRIPTION OF THE EMBODIMENT

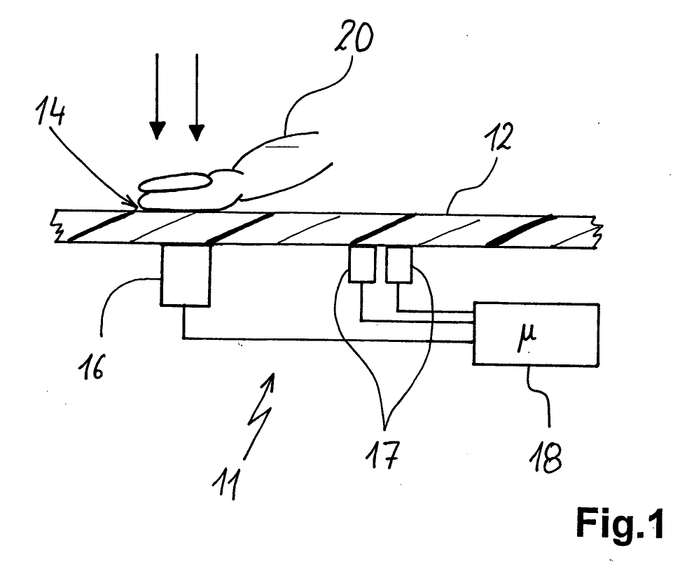

FIG. 1 shows an operating device 11, which is placed on or has a glass ceramic plate 12. The glass ceramic plate 12 can e.g. be the plate of a hob. It can alternatively be made from a different material and have one or more operating surfaces 14. The operating surface 14 corresponds to that conventionally used when using contact switches, which particularly in the case of glass ceramic hob plates can be identified by corresponding markings or colour imprints or impressions on the top side.

Under the glass ceramic plate 12 or more precisely under the operating surface 14 is provided a capacitive contact switch 16, particularly in the form of a capacitive sensor element, such as is e.g. known from DE 197 06 168 A, to which express reference is made in this connection. Alternatively, alongside the capacitive contact switch 16 are provided optical contact switches 17, which e.g. operate as reflected light barriers. The contact switches 16 and 17 are connected to a control mechanism 18 which controls them and with which their output signals are evaluated, particularly with respect to the existence of an operating action.

As shown, a finger 20 is placed on the operating surface 14. The two arrows illustrate that it is applied twice. If this double application or touching takes place within a specific, predetermined time, e.g. within one second, this is detected by the control mechanism 18. Control mechanism 18 then initiates the operating function corresponding to this double touching, e.g. a switching on or off of an electrical appliance belonging to the operating device 11.

In place of a double touching or contacting, as shown in FIG. 1, a more frequent contacting may be necessary for initiating an operating function. It is alternatively possible to associate different frequency contacting with different operating functions. It is additionally possible to vary the time interval within which the double or multiple contacting must take place, particularly also as a function of the frequency of contacting for initiating the operating function.

To bring about an adaptation to the operating behaviour of an operator, it is possible to set the time within which the multiple contacting or touching must take place in order to initiate an operating function, particularly in the setting mode of the operator. This leads to a type of operator or user adaptation.

1. An operating method for an electrical appliance, said electrical appliance having an operating surface and a contact switch or contact sensor, the contact switch or the contact sensor being placed on or under the operating surface, wherein contacting for operation takes place on the operating surface, the method comprising the steps of:
detecting a twice or multiply succeeding contacting of the operating surface on or over the contact switch or the contact sensor within a specific time or with a specific frequency; and
initiating an operating function as a result of said detection.

2. The operating method according to claim 1, wherein only a multiple contacting operation at a single point or on a single contact switch or contact sensor is evaluated as being associated or successive for initiating said operating function.

3. The operating method according to claim 1, wherein said contacting takes place with a force corresponding to a gentle, audible touching with one finger.

4. The operating method according to claim 1, wherein a time interval between two said successive touching operations is less than two seconds.

5. The operating method according to claim 4, wherein said time interval between two said successive touching operations is under one second.

6. The operating method according to claim 1, wherein no operating function is initiated or no operating action detected when there has only been a single contacting of said contact switch or said contact sensor.

7. The operating method according to claim 1, wherein no operating function is initiated after contacting said contact switch or said contact sensor only once and wherein this is subsequently indicated to an operator.

8. The operating method according to claim 1, wherein a distinction is made between a double contacting and a further extending triple or multiple contacting, and wherein in each case different operating functions are initiated.

9. The operating method according to claim 1, wherein each one of said individual contacting is at least briefly indicated by optical or acoustic indication or display.

10. The operating method according to claim 1, wherein said initiation of said intended operating function is indicated by an optical or acoustic indication or display.

11. An operating device for performing the operating method according to claim 1, comprising at least one said contact switch or said contact sensor on or below said operating surface on which contacting for operating purposes takes place.
